(19) United States
(12) Patent Application Publication
(10) Pub. No.: US 2011/0012178 A1
(43) Pub. Date: Jan. 20, 2011

(54) SEMICONDUCTOR WAFER, METHOD OF MANUFACTURING A SEMICONDUCTOR WAFER, AND SEMICONDUCTOR DEVICE

(76) Inventors: Masakazu Sugiyama, Kanagawa (JP); Yukihiro Shimogaki, Tokyo (JP); Masahiko Hata, Ibaraki (JP); Osamu Ichikawa, Chiba (JP)

Correspondence Address: SUGHRUE MION, PLLC, 2100 PENNSYLVANIA AVENUE, N.W., SUITE 800, WASHINGTON, DC, 20037, US

(21) Appl. No.: 12/934,474

(22) PCT Filed: Mar. 26, 2009
(86) PCT No.: PCT/JP2009/001373

§ 371 Date: Sep. 24, 2010

(51) Int. Cl. H01L 29/20; H01L 21/20; H01L 29/78

(52) U.S. Cl. 257/288; 257/615; 438/478; 257/E29.089; 257/E21.09; 257/E29.255

(57) ABSTRACT

Provided is a semiconductor wafer having decreased interface state density at the semiconductor-insulator interface, a method of manufacturing this semiconductor wafer, and a semiconductor device.

Provided is a semiconductor wafer comprising a group 3-5 compound semiconductor layer containing arsenic; and an insulating layer that is an oxide, a nitride, or an oxynitride, wherein arsenic oxides are not detected between the semiconductor layer and the insulating layer. This semiconductor wafer may be such that, when using X-ray photoelectron spectroscopy to observe photoelectron intensity of an element existing between the semiconductor layer and the insulating layer, an oxide peak caused by oxidized arsenic is not detected on a higher bonding energy side of an element peak caused by the arsenic.

### TECHNICAL FIELD

The present invention relates to a semiconductor wafer, a method of manufacturing a semiconductor wafer, and a semiconductor device. In particular, the present invention relates to a semiconductor device that has a compound semiconductor containing arsenic, in which the interface state density in an MIS configuration is decreased, a semiconductor wafer for manufacturing this semiconductor device, and a method of manufacturing the semiconductor wafer.

### BACKGROUND ART

A MISFET (Metal Insulator Semiconductor Field Effect Transistor) using a compound semiconductor in the channel layer is expected to serve as a switching device suitable for high-frequency and high-power operation. However, there is a problem that an interface state is formed between the semiconductor and the insulator. An effective method for decreasing the interface state density involves processing the surface of the compound semiconductor with a sulfide, as described in Non-Patent Document 1.

Non-Patent Document 1: S. Arabasz, et al., Vac. 80, 2006, pg. 888

### DISCLOSURE OF THE INVENTION

### Problems to Be Solved by the Invention

It is an object of the present invention to provided a semiconductor device that has decreased interface state density between the semiconductor and the insulator, and a method for manufacturing such a semiconductor wafer. As described above, during actual application of a compound semiconductor MISFET, decreasing the interface state density is a recognized goal. Therefore, the inventors of the present invention performed rigorous investigation of the causes that affect the interface state, and achieved the present invention based on the discovery that oxidation at the semiconductor/insulator interface (referred to hereinafter simply as the “interface”) has a significant effect on the interface state.

### Means for Solving the Problems

According to a first aspect of the present invention for solving the above problems, provided is a semiconductor wafer comprising a group 3-5 compound semiconductor layer containing arsenic; and an insulating layer that is an oxide, a nitride, or an oxynitride, wherein arsenic oxides are not detected between the semiconductor layer and the insulating layer. This semiconductor wafer may be such that, when using X-ray photoelectron spectroscopy to observe photoelectron intensity of an element existing between the semiconductor layer and the insulating layer, an oxide peak caused by oxidized arsenic is not detected on a higher bonding energy side of an element peak caused by the arsenic. Instead, this semiconductor wafer may be such that, when using X-ray photoelectron spectroscopy to observe photoelectron intensity of an element existing between the semiconductor layer and the insulating layer, a photoelectron peak from a 3 d orbit of arsenic bonded with oxygen is not detected on a higher bonding energy side of an element peak caused by the arsenic. Here, the photoelectron peak from the 3 d orbit of arsenic bonded with oxygen may be measured bonding energy range from 42 eV to 45 eV. The phrase “not detected” means that the target was not detected using current X-ray photoelectron spectroscopy measurement techniques, and it may be possible that future development of measurement techniques may result in detection of the target. Furthermore, when identifying a target element by applying a conformity analysis technique such as curve fitting to the measured X-ray photoelectron spectroscopy results, the phrase “not detected” is used when the fitting result from the curve fitting for a case where the target element is assumed to not exist sufficiently matches the actual measured data. Yet further, When the curve fitting results indicate that the “photoelectron peak from a 3 d orbit of arsenic bonded with oxygen” is sufficiently smaller than other peaks, the phrase “not detected” is used. For example, when the “photoelectron peak from a 3 d orbit of arsenic bonded with oxygen” is 1/10 or less of the other peaks, preferably 1/100 or less of the other peaks, it can be said that this photoelectron peak is not detected.

The semiconductor wafer of the first aspect may further comprise an intermediate layer that is formed between the semiconductor layer and the insulating layer, and that prevents oxidation of the arsenic. The intermediate layer may contain a group 6 element other than oxygen, and the group 6 element may be sulfur or selenium. The intermediate layer may contain a metal element that is oxidized or nitrided to become an insulator, and the intermediate layer may contain aluminum.

According to a second aspect of the present invention, provided is a method of manufacturing a semiconductor wafer, comprising epitaxially growing a group 3-5 compound semiconductor layer containing arsenic; and performing an anti-oxidation process on a surface of the semiconductor layer to prevent oxidation of the arsenic. The method of manufacturing a semiconductor wafer may further comprise holding the semiconductor layer in an atmosphere that does not contain arsenic, to remove excess arsenic from the surface of the semiconductor layer. Performing the anti-oxidation process may include forming a film that contains sulfur, selenium, or aluminum on the surface of the semiconductor layer. Performing the anti-oxidation process may include processing the semiconductor layer in an atmosphere containing hydrogen. Performing the anti-oxidation process may include forming a film on the semiconductor layer in an atmosphere containing hydrogen. The surface of the semiconductor layer prior to forming the film may be a Ga-stabilized surface with a (2×4) structure or a c(8×2) structure.

According to a third aspect of the present invention, provided is a method of manufacturing a semiconductor wafer, comprising epitaxially growing a group 3-5 compound semiconductor layer containing arsenic; holding the epitaxially grown semiconductor layer in an atmosphere that does not contain arsenic; and processing a surface of the held semiconductor layer in an atmosphere containing sulfur or selenium. The method of manufacturing a semiconductor wafer may further comprise processing the surface of the semiconductor layer, which has been processed in the atmosphere containing sulfur or selenium, in an atmosphere containing hydrogen. The atmosphere containing sulfur may include sulfur hydride. The atmosphere containing selenium may include selenium hydride. The method of manufacturing a semiconductor wafer may further comprise forming on a surface of the semiconductor wafer a film containing aluminum, sulfur, or selenium. Aluminum raw material for forming the film containing aluminum may be organic aluminum. Sulfur raw material for forming the film containing sulfur may be sulfur hydride. Selenium raw material for forming the film containing selenium may be selenium hydride. The surface of the semiconductor layer prior to forming the film may be a Ga-stabilized surface with a (2×4) structure or a c(8×2) structure. The method of manufacturing a semiconductor wafer may further comprise forming an insulating layer that is an oxide, a nitride, or an oxynitride.

According to a fourth aspect of the present invention, provided is a semiconductor wafer comprising a group 3-5 compound semiconductor containing arsenic; an insulator disposed on the group 3-5 compound semiconductor; and an intermediate layer that restricts oxidation of the arsenic and that is formed within the insulator or between the group 3-5 compound semiconductor and the insulator.

According to a fifth aspect of the present invention, provided is a semiconductor device comprising a group 3-5 compound semiconductor layer containing arsenic; an insulating layer that is an oxide, a nitride, or an oxynitride; and a control electrode on the insulating layer, wherein arsenic oxides are not detected between the semiconductor layer and the insulating layer. Instead, the fifth aspect may provide a semiconductor device comprising the semiconductor wafer according to the first aspect or the fourth aspect; and a control electrode on the insulating layer.

### BRIEF DESCRIPTION OF THE DRAWINGS

FIG. 1 shows an exemplary cross section of a semiconductor device 100 according to an embodiment of the present invention.

FIG. 2 shows an exemplary cross section of a step in a process for manufacturing the semiconductor device 100.

FIG. 3 shows an exemplary cross section of a step in a process for manufacturing the semiconductor device 100.

FIG. 4 shows an exemplary cross section of a step in a process for manufacturing the semiconductor device 100.

FIG. 5 shows an exemplary cross section of a step in a process for manufacturing the semiconductor device 100.

FIG. 6 shows an exemplary cross section of a step in a process for manufacturing the semiconductor device 100.

FIG. 7 shows a graph of experimental data obtained by observing the GaAs surface using reflection anisotropy spectroscopy.

FIG. 8 shows results of observing photoelectron intensity using X-ray photoelectron spectroscopy.

FIG. 9 shows a graph of experimental data obtained by observing the GaAs surface using reflection anisotropy spectroscopy.

FIG. 10 shows results of observing photoelectron intensity using X-ray photoelectron spectroscopy.

### LIST OF THE REFERENCE NUMERALS

100 semiconductor device
102 wafer
104 buffer layer
106 semiconductor layer
108 intermediate layer
110 insulating layer
112 control electrode
114 input/output electrode
120 film
122 film
124 conductive layer

### BEST MODE FOR CARRYING OUT THE INVENTION

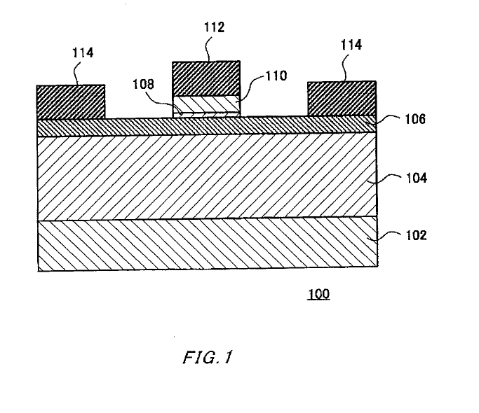

FIG. 1 shows an exemplary cross section of a semiconductor device 100 according to an embodiment of the present invention. The semiconductor device 100 includes a wafer 102, a buffer layer 104, a semiconductor layer 106, an intermediate layer 108, an insulating layer 110, a control electrode 112, and input/output electrodes 114.

The wafer 102 can be made of any material that allows a compound semiconductor crystal layer to be formed on a top surface thereof For example, the wafer 102 may be a single-crystal silicon wafer, a sapphire, or a single-crystal GaAs wafer.

The buffer layer 104 may be a compound semiconductor layer that lattice matches or pseudo-lattice matches with the semiconductor layer 106, and is formed between the wafer 102 and the semiconductor layer 106. The buffer layer 104 may be formed in order to increase the crystallinity of the semiconductor layer 106 or to decrease the effect of impurities from the wafer 102. The buffer layer 104 may be a GaAs layer that is undoped or doped with impurities. In this case, the GaAs layer can be formed using MOCVD (metalorganic chemical vapor deposition) with an organic metal as a raw material gas.

The semiconductor layer 106 may be a group 3-5 compound semiconductor containing arsenic. The semiconductor layer 106 may function as a functional layer of the electronic device, and when this electronic device is a MISFET, for example, the semiconductor layer 106 may be a channel layer in which channels of the FET are formed. The semiconductor layer 106 may be a GaAs layer. The semiconductor layer 106 may be doped with impurities, but need not be doped. When functioning as a channel layer of a MISFET, the semiconductor layer 106 is preferably doped with n-type impurities to become an n-type semiconductor. The semiconductor layer 106 may be formed using MOCVD with an organic metal gas as a raw material gas.

The insulating layer 110 may be an insulating layer made of an oxide, a nitride, or an oxynitride. When the electronic device is a MISFET, the insulating layer 110 functions as a gate insulating layer below a gate electrode, which is an example of the control electrode. The insulating layer 110 may be made of aluminum oxide, silicon oxide, tantalum oxide, hafnium oxide, zirconium oxide, aluminum nitride, silicon nitride, silicon oxynitride, or the like. When the insulating layer 110 functions as a gate insulating layer in a MISFET, the insulating layer 110 is preferably a material with a high dielectric constant. The insulating layer 110 can be formed by sputtering using the material that becomes the insulating layer 110 on a target.

The intermediate layer 108 is formed between the semiconductor layer 106 and the insulating layer 110, and prevents oxidation of the arsenic. According to the findings of the inventors of the present invention, an example of a material that can form an interface state of the semiconductor-insulator interface is an arsenic oxide. Accordingly, forming an intermediate layer 108 that prevents oxidation of arsenic at an interface between the semiconductor layer 106 and the insulating layer 110 restricts the oxidation of the arsenic, thereby decreasing the interface state density.

The intermediate layer 108 may include group 6 elements other than oxygen, and examples of such group 6 elements include sulfur and selenium. In particular, when the semiconductor layer 106 is a GaAs layer, sulfur is present as gallium sulfide at an interface between the intermediate layer 108 and the semiconductor layer 106. The gallium sulfide does not create an interface state, and therefore a stable interface can be formed.

The intermediate layer 108 may include a metal element that is oxidized or nitrided to become an insulator. This metal element may be aluminum, for example. In particular, aluminum oxide, which is oxidized aluminum, is chemically stable, and so when aluminum oxide is selected as the insulating layer 110, the intermediate layer 108 and the insulating layer 110 can be formed integrally, thereby enabling the intermediate layer 108 to function as a gate insulating layer.

The method for forming the intermediate layer 108 can be selected according to the material thereof. For example, when sulfur is used, thermal processing (thermal CVD) performed in an atmosphere of a gas containing sulfur, such as H₂S, can be selected. In the case of aluminum, MOCVD using an organic aluminum gas as the raw material can be selected. Other film formation methods can be used to form the intermediate layer 108, such as sputtering, and vapor deposition.

As described above, the intermediate layer 108 restricts the oxidation of the arsenic between the semiconductor layer 106 and the insulating layer 110. Therefore, at least according to current analysis techniques, no arsenic oxide compounds are detected between the semiconductor layer 106 and the insulating layer 110. For example, when observing a spectrum of photoelectron intensity using X-ray photoelectron spectroscopy targeting the elements between the semiconductor layer 106 and the insulating layer 110, the oxide peaks caused by oxidized arsenic are not detected on the high bonding energy side of the element peak caused by the arsenic. Here, the oxide peak caused by the oxidized arsenic refers to the photoelectron peak from a 3 d orbit of the arsenic bonded with oxygen.

The control electrode 112 is formed on the insulating layer 110. The control electrode 112 can function as a gate electrode of a MISFET, for example. The control electrode 112 may be any metal, polysilicon, metal silicide, or the like.

The input/output electrodes 114 function as source and drain electrodes of a MISFET, for example. An ohmic layer that achieves ohmic contact may be formed between the input/output electrodes 114 and the semiconductor layer 106. Any material that can achieve ohmic contact with the substrate material can be selected for the input/output electrodes 114. For example, the input/output electrodes 114 may be metals such as nickel, platinum, or gold, heavily doped polysilicon, metal silicide, or the like.

The above describes a semiconductor device 100, but the wafer 102, the buffer layer 104, the semiconductor layer 106, the intermediate layer 108, and the insulating layer 110 may be understood as forming a single semiconductor wafer. This semiconductor wafer is provided with the intermediate layer 108 and has a top surface that is covered by the insulating layer 110, and can therefore be distributed as a product that does not degrade the interface. It is not necessary to form the buffer layer 104 on the semiconductor wafer, and so the semiconductor layer 106 itself may be the wafer 102.

The above describes a MISFET as an example of the semiconductor device 100, but the semiconductor device 100 may be another type of electronic device. For example, the semiconductor device 100 may be a capacitor in which the intermediate layer 108 and the insulating layer 110 are sandwiched by the control electrode 112 and the semiconductor layer 106.

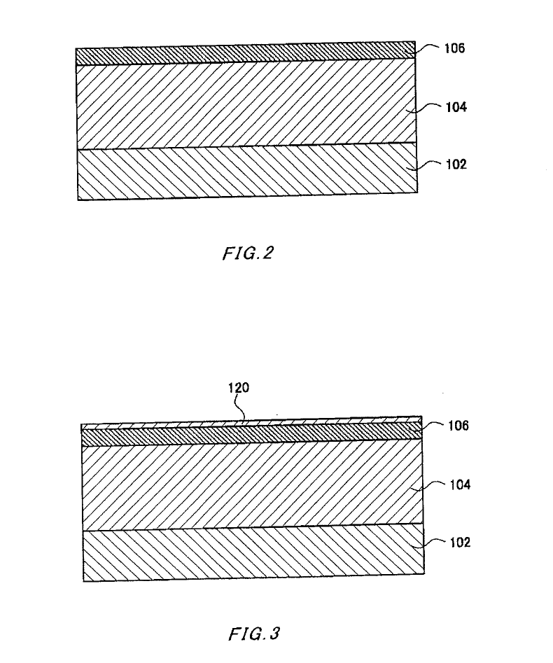

FIGS. 2 to 6 show exemplary cross sections in steps for manufacturing the semiconductor device 100. As shown in FIG. 2, the wafer 102 is prepared with the buffer layer 104 formed thereon and the semiconductor layer 106 formed on the buffer layer 104. The semiconductor layer 106 can be formed by epitaxial growth using MOCVD.

After forming the semiconductor layer 106, the semiconductor layer 106 is held in an atmosphere that does not contain arsenic, so that excess arsenic can be removed from the top surface of the semiconductor layer 106. By removing the excess arsenic, arsenic oxide can be decreased, and the effect of the drop in the interface state density of the intermediate layer 108 can be synergistically increased. The process for removing the excess arsenic can be realized at a temperature no less than 400° C., preferably no less than 600° C., and no greater than 620° C.

Instead, after forming the semiconductor layer 106 and after holding the semiconductor layer 106 in an atmosphere that does not contain arsenic so that excess arsenic can be removed from the top surface of the semiconductor layer 106, the top surface of the semiconductor layer 106 can be processed with an atmosphere that contains sulfur or selenium. After this processing, the semiconductor layer 106 may be held in an atmosphere that does not contain arsenic, sulfur, or selenium. Instead, the top surface of the semiconductor layer 106 that has been processed in an atmosphere that does not contain sulfur or selenium may be processed in an atmosphere containing hydrogen. As a result, the excess arsenic can be further removed.

With the above processing, the arsenic oxide can he further reduced, and the effect of the drop in the interface state density of the intermediate layer 108 can be synergistically increased. The processes for removing the excess arsenic, which include holding the semiconductor layer 106 in an atmosphere that does not contain arsenic, processing the top surface of the semiconductor layer 106 in an atmosphere containing sulfur or selenium, and processing the top surface of the semiconductor layer 106 in an atmosphere containing hydrogen, can each be performed at a temperature no less than 400° C. and no greater than 620° C., for example.

The atmosphere that does not contain arsenic can be selected from among a hydrogen atmosphere, an atmosphere of a non-volatile gas such as argon, or a vacuum atmosphere, and is preferably a hydrogen atmosphere. The processing in an atmosphere that contains sulfur or selenium can be thermal processing in an atmosphere containing a sulfur hydride gas or a selenium hydride gas, such as H₂S or H₂Se. The processing in an atmosphere that does not contain arsenic, sulfur, or selenium can use a hydrogen atmosphere, an atmosphere of a non-volatile gas such as argon, or a vacuum atmosphere, and is preferably a hydrogen atmosphere.

After forming the semiconductor layer 106, the semiconductor layer 106 is held in an atmosphere that does not contain arsenic, and the semiconductor top surface, which is the top surface of the semiconductor layer 106 from which the excess arsenic is removed, has a (2×4) Ga-stabilized surface structure. Furthermore, after surface processing the semiconductor layer 106 having the (2×4) Ga-stabilized surface structure in an atmosphere containing sulfur or selenium, the semiconductor layer 106 can be held in an atmosphere that does not contain arsenic, sulfur, or selenium. As a result, the excess arsenic can be further removed to achieve a c(8×2) Ga-stabilized surface.

Here, the (2×4) Ga-stabilized surface structure refers to a structure of a top surface of the (100) surface of a GaAs crystal expressed using Miller indices, according to Wood's notation. In this case, the (2×4) Ga-stabilized surface structure refers to a primitive lattice surface in which the Ga is exposed on the topmost surface and the periodic structure of the reconstructed surface is infinitely repeated in left-right and up-down directions with a 2×4 substrate crystal lattice as a single-unit structure. The c(8×2) Ga-stabilized surface is also expressed using Wood's notation, and refers to a primitive lattice surface that has as its face-centered lattice a periodic structure of a reconstructed surface of the GaAs crystal (100) surface in which the Ga is exposed in the topmost surface, and this periodic structure is infinitely repeated in left-right and up-down directions with an 8×2 substrate crystal lattice a single-unit structure.

As shown in FIG. 3, a film 120 containing sulfur, for example, is formed on the semiconductor layer 106 to become the intermediate layer 108. The formation of the film 120 can be understood as being a process for preventing oxidation of the arsenic, and the step of forming the film 120 can be understood as being a step of applying an anti-oxidation process to the top surface of the semiconductor layer 106. Instead of containing sulfur, the film 120 may contain selenium or aluminum. The aluminum raw material used for forming the film including aluminum may be organic aluminum. The sulfur raw material used for forming the film including sulfur may be sulfur hydride. The selenium raw material used for forming the film including selenium may be selenium hydride.

When forming the film 120 as an aluminum film, an organic aluminum gas such as a trimethylaluminum gas, dimethylaluminum hydride, triethylaluminum, or triisobutylaluminum may be used. When forming the film 120 as a gallium sulfide film or a gallium selenide film, H₂S gas or H₂Se gas may be used.

The step of forming the film 120 can be understood as being a step for thermally processing the semiconductor layer 106 in an atmosphere containing hydrogen. For example, thermal processing with H₂S as the raw material gas can be the processing in the atmosphere containing hydrogen.

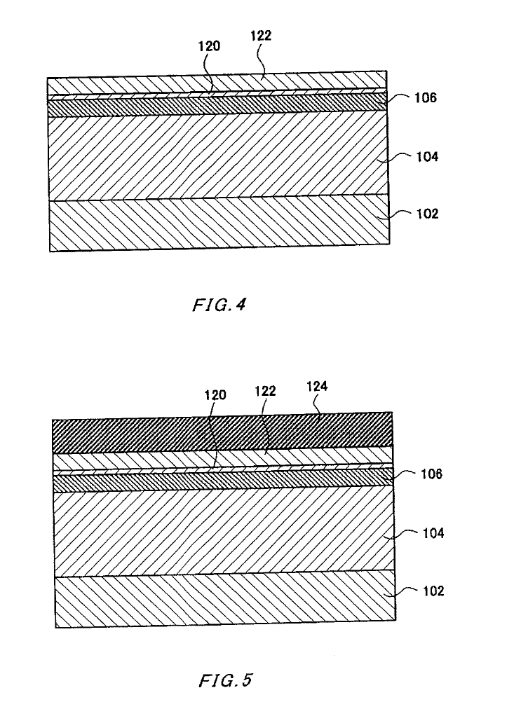

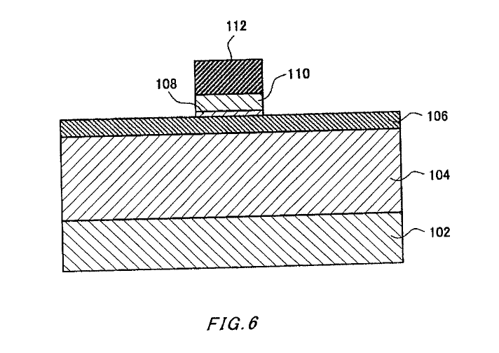

As shown in FIG. 4, a film 122 that becomes the insulating layer 110 is formed on the film 120. The film 122 may be an oxide, a nitride, or an oxynitride. Specifically, the film 122 may be aluminum oxide, silicon oxide, tantalum oxide, hafnium oxide, zirconium oxide, aluminum nitride, silicon nitride, or silicon oxynitride. The film 122 can be formed using sputtering, for example.

In the step of forming the film 122, when forming the oxide film, the film 122 may be placed in an oxidation environment. However, since the film 120 is formed in the present embodiment to become the intermediate layer 108 that prevents oxidation of the arsenic, oxidation of the top surface of the semiconductor layer 106 due to formation of the film 122 is restricted.

When forming, as the film 120 that becomes the intermediate layer 108, a film that contains an element such as aluminum that is oxidized or nitrided to become an insulator, many of the elements that become insulators through oxidizing or nitriding transform into insulators during the step of forming the film 122 that becomes the insulating layer 110 in an oxide or nitride atmosphere. As a result, the film 120 that becomes the intermediate layer 108 can restrict the surface oxidation of the semiconductor layer 106 and can function as an insulating film together with the insulating layer 110 after oxidization.

As shown in FIG. 5, the conductive layer 124 that becomes the control electrode 112 is formed. The conductive layer 124 may be any metal, polysilicon, metal silicide, or the like. The conductive layer 124 can be formed using CVD, sputtering, or the like.

As shown in FIG. 6, the conductive layer 124, the film 122, and the film 120 are patterned to form the control electrode 112, the insulating layer 110, and the intermediate layer 108. Next, the input/output electrodes 114 are formed by forming and patterning a conductive film, thereby manufacturing the semiconductor device 100 shown in FIG. 1.

In the semiconductor device 100 described above, the intermediate layer 108 restricts the surface oxidation of the semiconductor layer 106, and so the arsenic oxidation is restricted between the semiconductor layer 106 and the insulating layer 110, which are formed below the control electrode 112. As a result, the interface state density is decreased, enabling manufacturing of a practical compound semiconductor MISFET.

### First Embodiment

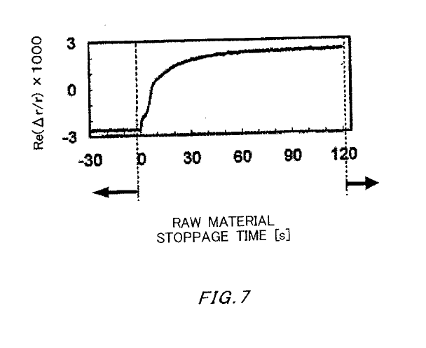

FIG. 7 shows a graph of experimental data obtained by observing the GaAs surface using reflection anisotropy spectroscopy. After holding the GaAs (001) wafer in a reaction chamber, arsenic raw material gas (tributyl arsenic) was supplied, and the wafer was heated to 600° C. The surface state after the supply of arsenic raw material gas was stopped was confirmed to have stabilized within two minutes. The change in the surface state is due to the removal of the excess arsenic, and it is therefore understood that approximately two minutes are necessary for the excess arsenic to be removed from the surface. The atmosphere after the supply of arsenic raw material gas is stopped may be a vacuum (low pressure) or an atmosphere of a non-volatile gas such as Argon.

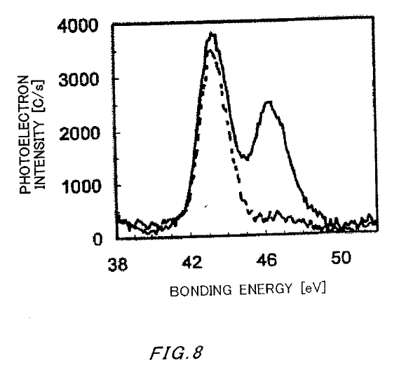

FIG. 8 shows results of observing photoelectron intensity using X-ray photoelectron spectroscopy. The dotted line indicates the results when processing with a gas containing sulfur is used to form the intermediate layer 108 of the present embodiment, and the solid line shows a case where gas containing sulfur was not used. The processing with a gas containing sulfur involved supplying H₂S for 5 minutes at a temperature of 600° C. Before the sulfur gas processing, the knowledge described in relation to FIG. 7 was applied to remove the excess arsenic.

In FIG. 8, the peak observed near a bonding energy of 43.5 eV is caused by arsenic 3 d, and the peak that is seen near 46 eV on the higher coupling energy side of the arsenic 3 d peak is known to be caused by chemical shift due to oxidation of the arsenic. As understood from FIG. 8, the chemical shift of the arsenic 3 d, which is due to the oxidized arsenic that can be observed when the sulfur gas processing is not performed, cannot be seen when the sulfur gas processing is performed, i.e. when the intermediate layer 108 of the present embodiment is formed.

In other words, when observing the photoelectron intensity using X-ray photoelectron spectroscopy, an oxidation peak caused by oxidized arsenic was not detected on the higher bonding energy side of the element peak caused by the arsenic. Therefore, it is understood that, at least with current analyzing techniques, arsenic oxides are not detected on the top surface of the GaAs, i.e. the semiconductor layer 106.

### Second Embodiment

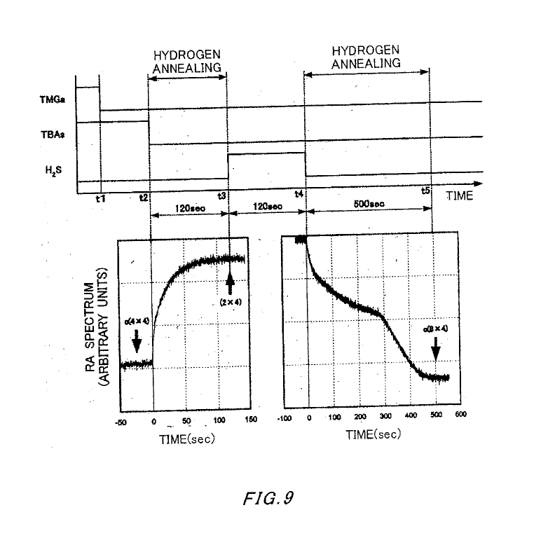

FIG. 9 shows a graph of experimental results obtained by observing the GaAs surface using reflection anisotropy spectroscopy. In FIG. 9, the upper portion shows the gas sequence. The horizontal axis, which indicates time, of the graph is shown to match the horizontal axis, which indicates time, of the gas sequence.

At time t1, the epitaxial growth of GaAs was stopped, and the GaAs (001) surface was held in a reaction chamber until time t2 while arsenic raw material gas (tributyl arsenic) and carrier gas (H₂) were supplied thereto. The GaAs was held at a temperature of 600° C. The GaAs surface in this state was determined to have a c(4×4) surface based on the shape of the spectrum obtained by reflection anisotropy spectroscopy.

The supply of arsenic raw material gas was stopped at time t2, and only the carrier gas (H₂) continued being supplied. The surface state was confirmed to have stabilized in approximately two minutes. In other words, the change of the surface state in this state is due to the removal of the arsenic, and so it is understood that approximately two minutes are needed to remove the excess arsenic from the surface. After stopping the supply of arsenic raw material gas, the surface stabilized in about two minutes (time t3), and the GaAs surface at this time was determined to have a (2×4) Ga-stabilized surface, based on the shape of the spectrum obtained by reflection anisotropy spectroscopy. The atmosphere after the supply of arsenic raw material gas is stopped may be, instead of H₂, a vacuum (low pressure) or an atmosphere of a non-volatile gas such as argon.

Hydrogen sulfide gas and carrier gas (H7) were supplied at time t3, and the GaAs surface then stabilized in two minutes at time t4. The supply of hydrogen sulfide gas was then stopped at time t4 and the carrier gas (H₂) continued to be supplied for processing in a hydrogen atmosphere, and the GaAs surface stabilized approximately 500 seconds after this at time t5. The GaAs surface at this time was determined to have a c(8×2) Ga-stabilized surface, based on the shape of the spectrum obtained by reflection anisotropy spectroscopy.

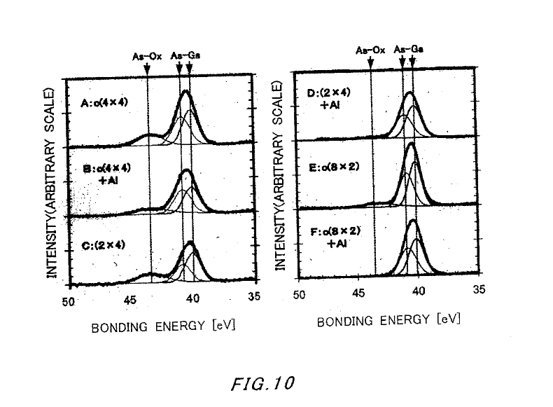

FIG. 10 shows results of observing photoelectron intensity using X-ray photoelectron spectroscopy. In FIG. 10, the upper left section A shows results of a spectrum observed for a test material that resulted from GaAs with a c(4×4) surface being placed as-is in an ambient environment. The middle left section B of FIG. 10 shows results of a spectrum observed for a test material that resulted from GaAs with a c(4×4) surface being placed in an ambient environment after forming thereon an anti-oxidation layer containing aluminum. The lower left section C of FIG. 10 shows results of a spectrum observed for a test material that resulted from GaAs with a (2×4) Ga-stabilized surface being placed as-is in an ambient environment. The upper right section D of FIG. 10 shows results of a spectrum observed for a test material that resulted from GaAs with a (2×4) Ga-stabilized surface being placed in an ambient environment after forming thereon an anti-oxidation layer containing aluminum. The middle right section E of FIG. 10 shows results of a spectrum observed for a test material that resulted from GaAs with a c(8×2) Ga-stabilized surface being placed as-is in an ambient environment. The lower right section F of FIG. 10 shows results of a spectrum observed for a test material that resulted from GaAs with a c(8×2) Ga-stabilized surface being placed in an ambient environment after forming thereon an anti-oxidation layer containing aluminum.

In sections A to F of FIG. 10, peak separation results obtained using curve fitting are shown together with the spectrum observation results. For example, in section A of FIG. 10, the spectrum observation results are separated into three Gaussian curves. These three Gaussian curves have respective peaks at approximately 40 eV, 41 eV, and 43.5 eV. The Gaussian curves having peaks at 40 eV and 41 eV can be identified as the photoelectron peaks from the 3 d orbit of the arsenic bonded with gallium, and the Gaussian curve with a peak at 43.5 eV can be identified as the photoelectron peak from the 3 d orbit of the arsenic bonded with oxygen. in other words, the amount of arsenic bonded with oxygen can be measured according to the height of the Gaussian curve having the 43.5 eV peak. Due to differences in measurement conditions or the like, the spectrum observation results of FIG. 8 and the spectrum observation results of FIG. 10 have slightly different values on their horizontal axes, i.e. slightly different energy values.

The following points were understood from the results shown in sections A to F of FIG. 10. First, based on the ratio between A and B, the ratio between C and D, and the ratio between F. and F, the amount of arsenic bonded to oxygen is lower when the anti-oxidation layer containing aluminum is formed than when nothing is formed. Second, based on ratios between A, C, and E and ratios between B, D, and F, the GaAs with a c(4×4) surface is more easily oxidized than the GaAs with a (2×4) Ga-stabilized surface, and the GaAs with a (2×4) Ga-stabilized surface is more easily oxidized than the GaAs with a c(8×2) Ga-stabilized surface. The GaAs surface that is hardest to oxidize is shown in section F of FIG. 10, which shows results for the case where the anti-oxidation layer containing aluminum was formed on the GaAs with a c(8×2) Ga-stabilized surface. In this case, the peak caused by oxidized arsenic is completely absent, at least with the current measurement accuracy. In the case shown in section D of FIG. 10, where the anti-oxidation layer containing aluminum was formed on the GaAs with a (2×4) Ga-stabilized surface, there is almost no peak caused by oxidized arsenic, and a photoelectron peak from the 3 d orbit of arsenic bonded with oxygen was not detected.

Based on the above, GaAs having a (2×4) Ga-stabilized surface or a c(8×2) Ga-stabilized surface was able to restrict the generation of arsenic bonded with oxygen. Furthermore, the anti-oxidation layer containing aluminum was able to restrict the generation of arsenic bonded with oxygen. In particular, when the anti-oxidation layer containing aluminum was formed on GaAs having a (2×4) Ga-stabilized surface or a c(8×2) Ga-stabilized surface, the generation of arsenic bonded with oxygen was almost completely prevented, and when the anti-oxidation layer containing aluminum was formed on GaAs having a c(8×2) Ga-stabilized surface, the generation of arsenic bonded with oxygen was not detected. By restricting or eliminating the generation of arsenic bonded with oxygen in these ways, the interface state density at the interface between the semiconductor layer 106 and the intermediate layer 108 can be decreased.

1. A semiconductor wafer comprising:
a group 3-5 compound semiconductor layer containing arsenic; and an
insulating layer that is an oxide, a nitride, or an oxynitride, wherein
arsenic oxides are not detected between the semiconductor layer and the insulating layer.

2. The semiconductor wafer according to claim 1, wherein
when using X-ray photoelectron spectroscopy to observe photoelectron intensity of an element existing between the semiconductor layer and the insulating layer, a photoelectron peak from a 3 d orbit of arsenic bonded with oxygen is not detected on a higher bonding energy side of an element peak caused by the arsenic.

3. The semiconductor wafer according to claim 1, further comprising an intermediate layer that is formed between the semiconductor layer and the insulating layer, and that prevents oxidation of the arsenic.

4. The semiconductor wafer according to claim 3, wherein the
intermediate layer contains a group 6 element other than oxygen.

5. The semiconductor wafer according to claim 4, wherein the group 6 element is sulfur or selenium.

6. The semiconductor wafer according to claim 3, wherein the
intermediate layer contains a metal element that is oxidized or nitrided to become an insulator.

7. The semiconductor wafer according to claim 6, wherein the
intermediate layer contains aluminum.

8. A method of manufacturing a semiconductor wafer, comprising:
epitaxially growing a group 3-5 compound semiconductor layer containing arsenic; and
performing an anti-oxidation process on a surface of the semiconductor layer to prevent oxidation of the arsenic.

9. The method of manufacturing a semiconductor wafer according to claim 8, further comprising holding the semiconductor layer in an atmosphere that does not contain arsenic, to remove excess arsenic from the surface of the semiconductor layer.

10. The method of manufacturing a semiconductor wafer according to claim 8, wherein
performing the anti-oxidation process includes forming a film that contains sulfur, selenium, or aluminum on the surface of the semiconductor layer.

11. The method of manufacturing a semiconductor wafer according to claim 8, wherein
performing the anti-oxidation process includes processing the semiconductor layer in an atmosphere containing hydrogen.

12. The method of manufacturing a semiconductor wafer according to claim 8, wherein
performing the anti-oxidation process includes forming a film on the semiconductor layer in an atmosphere containing hydrogen.

13. The method of manufacturing a semiconductor wafer according to claim 10, wherein
the surface of the semiconductor layer prior to forming the film is a Ga-stabilized surface with a (2×4) structure or a c(8×2) structure.

14. A method of manufacturing a semiconductor wafer, comprising:
epitaxially growing a group 3-5 compound semiconductor layer containing arsenic;
holding the epitaxially grown semiconductor layer in an atmosphere that does not contain arsenic; and
processing a surface of the held semiconductor layer in an atmosphere containing sulfur or selenium.

15. The method of manufacturing a semiconductor wafer according to claim 14, further comprising processing the surface of the semiconductor layer, which has been processed in the atmosphere containing sulfur or selenium, in an atmosphere containing hydrogen.

16. The method of manufacturing a semiconductor wafer according to claim 14, wherein
the atmosphere containing sulfur includes sulfur hydride.

17. The method of manufacturing a semiconductor wafer according to claim 14, wherein
the atmosphere containing selenium contains selenium hydride.

18. The method of manufacturing a semiconductor wafer according to claim 14, further comprising forming on a surface of the semiconductor wafer a film containing aluminum, sulfur, or selenium.

19. The method of manufacturing a semiconductor wafer according to claim 18, wherein
aluminum raw material for forming the film containing aluminum is organic aluminum.

20. The method of manufacturing a semiconductor wafer according to claim 18, wherein
sulfur raw material for forming the film containing sulfur is sulfur hydride.

21. The method of manufacturing a semiconductor wafer according to claim 18, wherein
selenium raw material for forming the film containing selenium is selenium hydride.

22. The method of manufacturing a semiconductor wafer according to claim 18, wherein
the surface of the semiconductor layer prior to forming the film is a Ga-stabilized surface with a (2×4) structure or a c(8×2) structure.

23. The method of manufacturing a semiconductor wafer according to claim 8, further comprising forming an insulating layer that is an oxide, a nitride, or an oxynitride.

24. A semiconductor wafer comprising:
a group 3-5 compound semiconductor containing arsenic;
an insulator disposed on the group 3-5 compound semiconductor: and
an intermediate layer that restricts oxidation of the arsenic and that is formed within the insulator or between the group 3-5 compound semiconductor and the insulator.

25. A semiconductor device comprising:
the semiconductor wafer according to claim 1;
and a control electrode on the insulating layer.
